(19) United States
(12) Patent Application Publication
(10) Pub. No.: US 2024/0169181 A1
(43) Pub. Date: May 23, 2024

(54) SIGNAL PROCESSOR AND SIGNAL PROCESSING METHOD

(71) Applicant: TDK CORPORATION, Tokyo (JP)

(72) Inventor: Yukio TERASAKI, Tokyo (JP)

(73) Assignee: TDK CORPORATION, Tokyo (JP)

(21) Appl. No.: 18/239,332

(22) Filed: Aug. 29, 2023

Related U.S. Application Data
(63) Continuation-in-part of application No. PCT/JP2022/043231, filed on Nov. 22, 2022.

(51) Int. Cl. G06N 3/044; G06N 3/063; G06N 5/04; H03M 1/12

(52) U.S. Cl. CPC G06N 3/044; G06N 3/063; G06N 5/04; H03M 1/1245

(57) ABSTRACT

A signal processor includes an input unit, an analog-digital converter, a control circuit, and a reservoir unit. The input unit receives a first analog signal. The analog-digital converter converts the first analog signal to a first digital signal. The control circuit detects the first analog signal or the first digital signal and outputs a control signal for extracting a part of the first analog signal or the first digital signal. The reservoir unit receives at least a part of the first digital signal and operates in synchronization with at least a part of the control signal.

### TECHNICAL FIELD

The present invention relates to a signal processor and a signal processing method.

### BACKGROUND ART

A neuromorphic device is a device that imitates the human brain using a neural network. A neuromorphic device artificially imitates a relationship between neurons and synapses in the human brain.

For example, a neuromorphic device includes nodes that are hierarchically arranged (neurons in the brain) and transmission means that connect the nodes (synapses in the brain). A neuromorphic device enhances a rate of correct answers to questions by training the transmission means (synapses). Learning is finding knowledge from information which is likely to be used in the future, and a neuromorphic device weights data that it receives.

A recurrent neural network is known as one of the neural network. A recurrent neural network can handle nonlinear time-series data. Nonlinear time-series data is the data whose value changes with the elapse of time, and stock prices is one of such examples. A recurrent neural network can process time-series data by feeding processing results of neurons in a subsequent stage back to neurons in a preceding stage.

Reservoir computing is a means for realizing a recurrent neural network. Reservoir computing performs a recursive processing by having signals to interact based on the internal coupling. Reservoir computing is performed by a reservoir computer device.

Short-term memory property is one of the performance metrics required for a reservoir computer device. Short-term memory property is a criterion for determining how past information can be stored or forgotten. In general, a reservoir computer device having short-term memory property optimal for a given task, outputs an estimated solution by considering data in a required section up to the current time from time-series data and ignoring unnecessary past data older before. For example, a reservoir computer device with excellent short-term memory property outputs an estimated solution in additional consideration of past data in time-series data, but a reservoir computer device with poor short-term memory property outputs an estimated solution using most recent data in time-series data.

Particularly, in the field of physical reservoirs in which reservoir computing is realized by physical devices or electronic devices which have been recently studied, it is known that the short-term memory property of a reservoir computer is generally low.

When the short-term memory property of a reservoir computer device is improved, it is possible to perform more advanced information processing. For example, it is described in Patent Document 1 that a first reservoir taking charge of short-term memory and a second reservoir taking charge of nonlinear processing are used to enhance short-term memory property of a reservoir computer device.

### CITATION LIST

### Patent Document

[Patent Document 1]
PCT International Publication No. WO2022/024167

### SUMMARY OF INVENTION

### Technical Problem

Short-term memory property and nonlinear transformation performance are known as significant aspects of performance required for a reservoir computer, but short-term memory property and nonlinear transformation performance have a trade-off relationship and thus it is difficult to satisfy both together. Accordingly, there are needs for a new method satisfying both properties.

The present invention was made in consideration of the aforementioned circumstances and provides a signal processor and a signal processing method for realizing a reservoir computer device having the equivalent performance as a reservoir computer device with excellent short-term memory property.

### Solution to Problem

(1) A signal processor according to a first aspect includes an input unit, an analog-digital converter, a control circuit, and a reservoir unit. The input unit receives a first analog signal. The analog-digital converter converts the first analog signal to a first digital signal. The control circuit detects the first analog signal or the first digital signal and outputs a control signal for extracting a part of the first analog signal or the first digital signal. The reservoir unit receives at least a part of the first digital signal and operates in synchronization with at least a part of the control signal.

(2) In the signal processor according to the aspect, the control circuit may include a first detection unit configured to detect the first analog signal and a first control unit configured to output the control signal when the first analog signal satisfies a setting condition. The first control unit may send the control signal to the analog-digital converter. The analog-digital converter may change a sampling timing at which the first analog signal is converted to the first digital signal at a timing at which the control signal has been input.

(3) In the signal processor according to the aspect, the control circuit may include a second detection unit configured to detect the first analog signal, a second control unit configured to output the control signal when the first analog signal satisfies a setting condition, and an extraction unit configured to extract a part of the first digital signal at a timing at which the control signal has been input and to input the extracted part of the first digital signal to the reservoir unit.

(4) In the signal processor according to the aspect, the control circuit may include a third detection unit configured to detect the first digital signal, a third control unit configured to output the control signal when the first digital signal satisfies a setting condition, and an extraction unit configured to extract a part of the first digital signal at a timing at which the control signal has been input and to input the extracted part of the first digital signal to the reservoir unit.

(5) In the signal processor according to the aspect, the control circuit may include a fourth detection unit configured to detect the first digital signal, and a fourth control unit configured to output the control signal when the first digital signal satisfies a setting condition. The fourth control unit may send the control signal to the analog-digital converter. The analog-digital converter may change a sampling timing at which the first analog signal is converted to the first digital signal at a timing at which the control signal has been input.

(6) In the signal processor according to the aspect, the number of signals input to the reservoir unit in a predetermined period in accordance with the control signal from the control circuit may be equal to or less than short-term memory property of the reservoir unit.

(7) In the signal processor according to the aspect, the input unit may additionally receive a second analog signal.

(8) In the signal processor according to the aspect, the reservoir unit may perform reservoir computing one time in synchronization with every output of the control signal.

(9) In the signal processor according to the aspect, the control circuit may output the control signal when a correlation coefficient between a prescribed time-series signal pattern and the first analog signal or the first digital signal is equal to or greater than a set value.

(10) In the signal processor according to the aspect, the control circuit may output the control signal when an accumulated square error of a prescribed time-series signal pattern and the first analog signal or the first digital signal is equal to or greater than a set value.

(11) In the signal processor according to the aspect, the control circuit may store a noise pattern and output the control signal when a correlation coefficient between the noise pattern and the first analog signal or the first digital signal is equal to or less than a set value.

(12) In the signal processor according to the aspect, the sampling control circuit may output the control signal when a change per unit time of the first analog signal or the first digital signal is equal to or greater than a set value.

(13) In the signal processor according to the aspect, the reservoir unit may operate in synchronization with at least a part of the control signal and perform learning based on an input signal, and an output condition of the control signal at the time of learning may be the same as an output condition of the control signal at the time of inference.

(14) In the signal processor according to the aspect, the reservoir unit may be realized as a state machine by logical circuits, an operation signal of the state machine may be synchronized with at least a part of the sampling control signal, and the reservoir unit may perform reservoir computing one time based on the operation signal.

(15) In the signal processor according to the aspect, the reservoir unit may be realized as a physical reservoir by elements or circuits, an input signal may be input to the physical reservoir in synchronization with at least a part of the sampling control signal, and the reservoir unit may perform reservoir computing one time based on the input signal.

(16) A signal processing method according to a second aspect includes: detecting an input first analog signal or a first digital signal to which the first analog signal is converted; outputting a control signal for extracting a part of the first analog signal or the first digital signal when the first analog signal or the first digital signal satisfies a setting condition; and performing inference through reservoir computing with a signal extracted using the control signal as an input.

### Advantageous Effects of Invention

With the signal processor and the signal processing method according to the aspects, it is possible to have the equivalent performance as a reservoir computer device with excellent short-term memory property even when short-term memory property of a reservoir computer device is low by extracting a signal greatly affecting an estimated solution.

### BRIEF DESCRIPTION OF DRAWINGS

FIG. 1 is a conceptual diagram of a signal processor according to a first embodiment.

FIG. 2 is a conceptual diagram of a reservoir unit according to the first embodiment.

FIG. 3 is a diagram illustrating signal processing which is performed by the signal processor according to the first embodiment.

FIG. 4 is a conceptual diagram of a signal processor according to a second embodiment.

FIG. 5 is a diagram illustrating signal processing which is performed by the signal processor according to the second embodiment.

FIG. 6 is a diagram illustrating signal processing which is performed by the signal processor according to the second embodiment.

FIG. 7 is a conceptual diagram of a signal processor according to a third embodiment.

FIG. 8 is a diagram illustrating signal processing which is performed by the signal processor according to the third embodiment.

FIG. 9 is a conceptual diagram of a signal processor according to a fourth embodiment.

FIG. 10 is a conceptual diagram of a signal processor according to a fifth embodiment.

### DESCRIPTION OF EMBODIMENTS

Hereinafter, embodiments of the present invention will be described in detail with reference to the accompanying drawings. In the drawings referred to in the following description, for the purpose of easy understanding of features of the present invention, featured constituents may be conveniently enlarged, and specific configurations of the constituents may be different from actual ones. Configurations in the following description are only exemplary examples, and the present invention is not limited thereto and can be appropriately modified within a range in which advantages of the present invention are achieved.

### First Embodiment

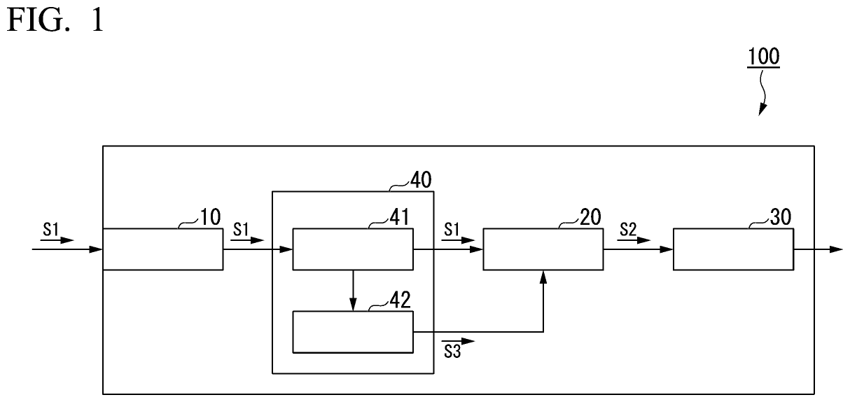

FIG. 1 is a conceptual diagram of a signal processor 100 according to a first embodiment. The signal processor 100 includes an input unit 10, an analog-digital converter 20 (hereinafter referred to as an ADC 20), a reservoir unit 30, and a sampling control circuit 40. The sampling control circuit 40 is an example of a control circuit in the claims.

The input unit 10 is an input terminal of the signal processor 100. An analog signal S1 is input to the input unit 10. The analog signal S1 is an example of a first analog signal. The input unit 10 is connected to, for example, a sensor. The input unit and the sensor may be connected in a wired manner or a wireless manner. The input unit 10 may be part of the sensor.

A known ADC can be used as the ADC 20 as long as it can convert an analog signal to a digital signal. The ADC 20 is, for example, an analog-digital conversion circuit. For example, the ADC 20 converts the analog signal S1 to a digital signal S2. The ADC 20 may be a part of the sensor along with the input unit 10. The sensor may include an interface that controls the ADC 20.

The reservoir unit 30 is a reservoir computer device that performs reservoir computing processing. The reservoir unit 30 converts an input signal nonlinearly and performs a learning process and an inference process.

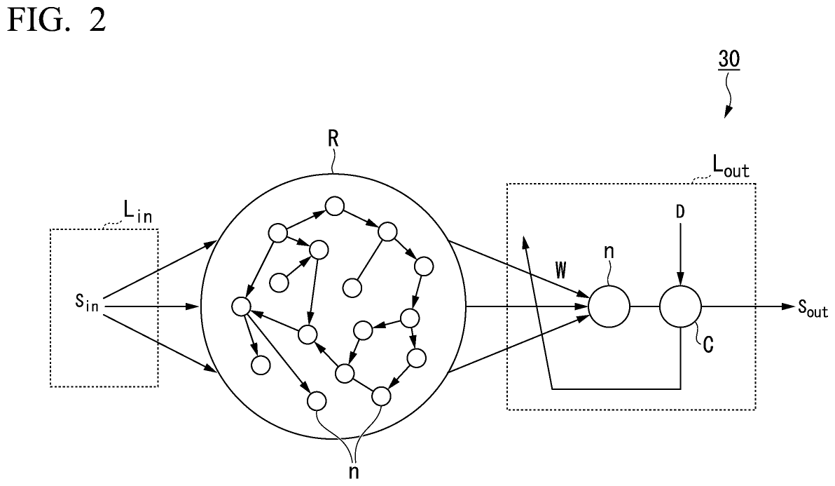

FIG. 2 is a conceptual diagram of the reservoir unit 30 according to the first embodiment. The reservoir unit 30 includes an input layer Lᵢₙ, a reservoir layer R, and an output layer Loin. The input layer Lᵢₙ and the output layer Lₒᵤₜ are connected to the reservoir layer R.

The input layer Lᵢₙ inputs an input signal Sᵢₙ to the reservoir layer R. The input signal Sᵢₙ is, for example, a digital signal input from the ADC 20. The reservoir unit 30 may not include the input layer Lᵢₙ. That is, the input signal Sᵢₙ may be input to the reservoir layer R without any change. The input signal Sᵢₙ may be weighted with a certain weight, and then the resultant signal may be input to the reservoir layer R.

The reservoir layer R stores the input signal Sᵢₙ input from the input layer Lᵢₙ and converts the input signal to another signal. The reservoir layer R includes a plurality of nodes n. In the reservoir layer R, coupling weights between the nodes n have fixed values set by predesigned coupling coefficients or the like, and the coupling weights between the nodes n are not generally learned. The coupling coefficients indicating the coupling weights between the nodes n are set, for example, using random numbers. The coupling coefficients indicating the coupling weights between the nodes n may be set, for example, to maximize the mutual information between an output signal and an expected signal. An output of each node n propagates to another node n via an activation function, and the input signal Sᵢₙ changes nonlinearly in the reservoir layer R. The input signal Sᵢₙ changes with the elapse of time by interacting in the reservoir layer R. The nodes n correspond to neurons in a neural circuit, and connections between the nodes n correspond to synapses. A plurality of nodes n are randomly connected. For example, a signal output from one node n at time t may return to the node n having output the signal at time t+1. The node n can perform a process in consideration of the signals at time t and time t+1, and information is recursively processed.

The output layer Lₒᵤₜ receives a signal from the reservoir layer R and outputs an output signal S out based on the signal. The output layer L out performs a learning process and an inference process. In the learning process, the output layer Lₒᵤₜ compares the output from the reservoir layer R with training data D using a comparator C and adjusts the coupling weights w between the nodes n of the reservoir layer R and the nodes n of the output layer Lₒᵤₜ. The coupling weights w are determined at the time of learning. In the inference process, the output layer Lₒᵤₜ outputs an inference result based on the input signal Su, and the coupling weights w as the output signal Sₒᵤₜ.

The reservoir unit 30 may be software or hardware. The software is a program installed in a computer. The reservoir unit 30 includes, for example, a memory that stores the program and a processor that executes the program. The hardware is a physical reservoir including a combination of real elements or circuits. The physical reservoir includes a plurality of circuits or elements corresponding to the nodes, which are connected to each other. The physical reservoir is formed by realizing the concept of reservoir computing using real elements or circuits. The reservoir unit 30 employing a digital circuit may be mounted in a programmable logic device (PLD) such as a field-programmable gate array (FPGA).

The sampling control circuit 40 detects an analog signal S1 and outputs a control signal S3 for extracting a part of the analog signal S1. The sampling control circuit 40 includes, for example, a first detection unit 41 and a first control unit 42.

The first detection unit 41 is connected to, for example, the input unit 10. The first detection unit 41 detects an analog signal S1. The first detection unit 41 is, for example, a detection device that monitors an analog signal S1. The first detection unit 41 may be a differential circuit that branches the analog signal S1 and extracts a temporal change thereof or a comparator circuit or an integral circuit that outputs a detection signal when a potential is greater than a specific value. The differential circuit, the comparator circuit, and the integral circuit may be replaced with other circuits having the similar functions.

The first control unit 42 is connected to, for example, the first detection unit 41. The first control unit 42 outputs a control signal S3 when the analog signal S1 satisfies a condition. The condition can be arbitrarily set according to a given task. The first control unit 42 is, for example, a program that is stored in the memory of the computer and executed by the processor. The first control unit 42 may have a function of changing detection conditions of the first detection unit 41. For example, the first control unit 42 can change a reference voltage of a comparator by using a variable resistor or selecting a plurality of resistors and change detection conditions of the first detection unit 41. The first control unit 42 is connected to, for example, the ADC 20.

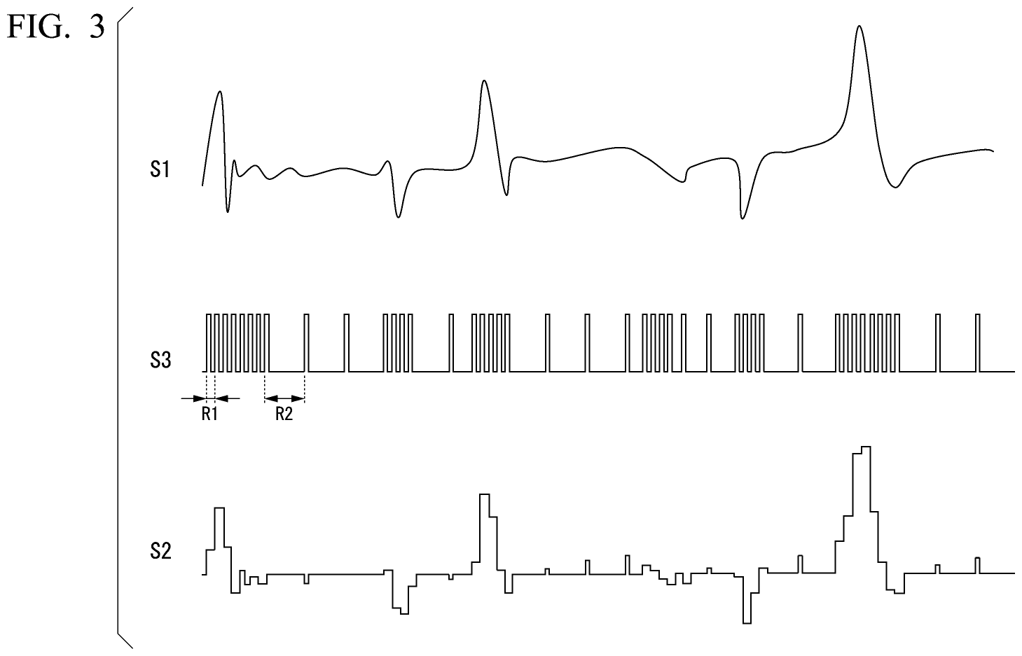

The operation of the signal processor 100 will be described below. FIG. 3 is a diagram illustrating signal processing that is performed by the signal processor 100.

First, an analog signal S1 detected by the sensor or the like is input to the signal processor 100 via the input unit 10. The analog signal S1 propagates to the first detection unit 41 and the ADC 20. The analog signal S1 propagates, for example, from the input unit 10 to the ADC 20, and a part thereof branches and propagates to the first detection unit 41.

The first detection unit 41 determines whether the analog signal S1 satisfies a setting condition. The first control unit 42 outputs the control signal S3 when the first detection unit 41 determines that the analog signal S1 satisfies the setting condition and does not output the control signal S3 when it is determined that the analog signal S1 does not satisfy the setting condition.

For example, the first detection unit 41 determines that the setting condition is satisfied when a change per unit time of the analog signal S1 is equal to or greater than a set value. That is, the control signal S3 may be set to be output when a change width of the analog signal S1 is large On the other hand, the first detection unit 41 may determine that the setting condition is satisfied when the change per unit time of the analog signal S1 is equal to or less than the set value. That is, the control signal S3 may be set to be output when the change width of the analog signal S1 is small For example, when the first detection unit 41 is a differential circuit, this condition setting can be performed.

For example, the first detection unit 41 may compare the analog signal S1 with a reference potential and determine that the setting condition is satisfied when a potential based on the analog signal S1 is greater than the reference potential. For example, when the first detection unit 41 is a comparator circuit, this condition setting can be performed.

For example, the first detection unit 41 may compare an integrated potential based on the analog signal S1 with the reference potential and determine that the setting condition is satisfied when the integrated potential is greater than the reference potential. For example, when the first detection unit 41 is an integral circuit, this condition setting can be performed.

In the signal processor 100, the first control unit 42 outputs the control signal S3 and sends the control signal to the ADC 20. The control signal S3 is a signal for instructing to change a sampling timing of the ADC 20. When the sampling timing is changed by the control signal S3, a period in which the analog signal S1 is converted to a digital signal S2 changes. When the sampling timing of the ADC 20 is changed by the control signal S3, a sampling rate of the ADC 20 changes, for example, from a first rate R1 to a second rate R2. The ADC 20 converts the analog signal S1 to the digital signal S2. The digital signal S2 is an example of a first digital signal. The signal processor 100 does not convert the whole analog signal S1 to the digital signal S2, but converts a part of the analog signal S1 to the digital signal S2 in accordance with the control signal S3. That is, a part of the analog signal S1 input to the signal processor 100 is sampled and is input as the digital signal S2 to the reservoir unit 30.

The number of signals input to the reservoir unit 30 in a predetermined period in response to the control signal S3 from the sampling control circuit 40 is, for example, equal to or less than short-term memory property of the reservoir unit 30. The predetermined period is, for example, a time corresponding to an interval (period) of an output signal S out to be detected. The time in which the input signal Sᵢₙ can theoretically affect a signal to be detected or the like may be set as the predetermined period.

The reservoir unit 30 stores past information corresponding to the short-term memory property and operates. When the number of signals input to the reservoir unit in the predetermined period is equal to or less than the short-term memory property, the reservoir unit 30 can perform learning or inference with using the past information in the period, and a rate of correction answers to a task is increased. A minimum sampling frequency that can maintain target performance may be set in the sampling control circuit 40. The sampling control circuit 40 performs control such that the number of signals input to the reservoir unit 30 in the predetermined period is equal to or greater than the minimum sampling frequency. The minimum sampling frequency can be calculated and acquired using a computer or the like.

Here, the short-term memory property which is an evaluation index of the reservoir unit 30 represents on how past information the state of the reservoir unit 30 in response to input time-series signals depends. The short-term memory property is expressed by an index such as a memory capacity (MC).

For example, regarding a task considering past information such as a parity task, when the maximum delay length with which the task is likely to succeed is defined as k, a degree of coincidence between a delay sequence (a delay time series) of the delay length k and an output series (an output time series) of a trained model can be expressed by a determination coefficient below. Here, the delay length k is a time by which an output signal is delayed with respect to an input signal through processing of the reservoir unit 30.

$$\\ \begin{matrix}[ Math . 1 ] & \\ {r}^{{}^{} 2} ( k ) = \frac{{Cov}^{{}^{} 2} ( u ( n - k ) , {\hat{y}}_{k} ( n ) )}{Var ( u ( n ) ) \cdot Var ( {\hat{y}}_{k} ( n ) )} & ( 1 )\end{matrix}$$

Here, n is a time step, y\hat{ }k(k) is an output of the reservoir unit 30 in the time step n when the delay length is k, and Cov(⋅,⋅) is covariance. When the delay series is completely restored (reproduced) by the reservoir unit 30, r² (k) represents a value of 1. The memory capacity MC is a sum of the determination coefficients r²(k) with respect to the delay length k and is expressed as follows.

[Math. 2]

MC=Σₖ₌₁^{∞}r²(k) (2)

On the other hand, for example, when reservoir computing is realized by a physical device, the memory capacity is often limited due to constraints in characteristics of physical phenomena, a device structure, and the like. In this case, when a signal of the sensor or the like is input to the reservoir unit 30 having the memory capacity MC without processing, redundant signals included in the sensor signal are input to the reservoir unit 30, and thus the limited memory capacity MC of the reservoir unit 30 cannot be utilized.

The short-term memory property (the memory capacity MC) expressed by Expression (2) is acquired by calculating a sum of correlations (mutual information) of a value output from the series and a preferable value over all the delay steps in processing the time-series signals. The short-term memory property expressed by Expression (2) can be suitably used to compare latent short-term memory property of the reservoir unit 30.

On the other hand, when the reservoir unit 30 is applied to a real task, the short-term memory property expressed by Expression (2) may not serve as an appropriate index. For example, when the reservoir unit 30 is applied to a real task, bigger memory capacity MC is not always better. In order to form a feature space required for the task, it is preferable that the reservoir unit 30 store necessary past series and forget the other past series. That is, it is important for the reservoir unit 30 to have appropriate short-term memory property for a target task, and it is important to have short-term memory property appropriate for a specific delay length (for example, T. Hulser et al, Nanophotnics 2023; 12(5): 937-947 “Deriving task specific performance from the information processing capacity of a reservoir computer” October 2022 and T. L. Carroll, “Optimizing Memory in Reservoir Computers”, January 2022).

That is, when a real task is assumed, the short-term memory property required for the task is a memory capacity for a necessary delay length. For example, it is necessary to adjust a sampling frequency such that the sampling frequency from a period of an input signal affecting task performance in a range of the delay length is maximized. That is, it is necessary to adjust the sampling counts acquired from a series of input signals to satisfy short-term memory property required for solving the real task. In this case, the short-term memory property is expressed by one of Expressions (3) to (5).

[Math. 3]

MC(k)=r²(k) (3)

[Math. 4]

MC=Σₖ₌₁^{∞}aₖ·r²(k) (4)

[Math. 5]

MC=Σₖ₌₁ⁿr²(k) (5)

As described above, the short-term memory property may be expressed by Expression (2) or may be expressed by one of Expressions (3) to (5). The short-term memory property expressed by Expressions (3) to (5) can be suitably used to solve the real task. The short-term memory property expressed by one of Expressions (3) to (5) is a partial memory capacity corresponding to the delay length required for the corresponding task.

The digital signal S2 is input to the reservoir unit 30. All the digital signals S2 may be input to the reservoir unit 30 or some thereof may be input to the reservoir unit 30. The reservoir unit 30 operates in synchronization with at least a part of the control signal S3. The reservoir unit 30 may operate synchronously whenever the control signal S3 is output. Synchronous operation means that the reservoir unit 30 performs reservoir computing one time according to a timing at which the control signal S3 has been output.

For example, when the reservoir unit 30 is realized as a state machine, inputting of the digital signal S2 to the reservoir unit 30 can be controlled by inputting an operation signal (a trigger signal) to the state machine. For example, when the operation signal (the trigger signal) is input to the state machine, the reservoir unit 30 performs reservoir computing one time. The operation signal is synchronized with at least a part of the control signal S3. When the operation signal is synchronized with the whole control signal S3, the reservoir unit 30 performs reservoir computing every time the control signal S3 is input.

For example, when the reservoir unit 30 is a physical reservoir, inputting of the digital signal S2 to the reservoir unit 30 can be controlled using a switch. An operation signal of the switch is synchronized with at least a part of the control signal S3. When the switch is turned on, an input signal is input to the reservoir unit 30 in synchronization with the control signal S3. When the operation signal is synchronized with the whole control signal S3, the reservoir unit 30 performs reservoir computing every time the control signal S3 is input. A latch timing at which the output signal Sₒᵤₜ of the physical reservoir is extracted to the outside may be synchronized with the control signal S3.

The reservoir unit 30 operates in synchronization with at least a part of the control signal S3 to convert the input signal Sᵢₙ nonlinearly and to perform inference. The reservoir unit 30 may operate synchronously to convert the input signal Sᵢₙ nonlinearly and to perform inference every time the control signal S3 is output.

It is preferable that the reservoir unit 30 also operate in synchronization with at least a part of the control signal S3 at the time of learning. It is preferable that an output condition of the control signal S3 at the time of learning be the same as an output condition of the control signal S3 at the time of inference. When the input signal Sᵢₙ input to the reservoir unit 30 satisfies the same condition at the time of performing of the learning process and at the time of performing of the inference process, it is possible to increase the rate of correct answers to a task in the reservoir unit 30.

As described above, the signal processor 100 according to the first embodiment samples the analog signal S1 input to the signal processor 100 and converts a part thereof to a digital signal S2, and thus an amount of signals input to the reservoir unit 30 decreases.

In reservoir computing, signals input to the reservoir layer R include signals greatly affecting an estimated solution and signals little affecting the estimated solution.

The signal processor 100 according to the first embodiment extracts the signals greatly affecting the estimated solution by selectively sampling the signals. Accordingly, since the reservoir unit 30 stores only the signals greatly affecting the estimated solution in a short term, it is possible to store information equivalent to that when the short-term memory property is high.

Accordingly, even when the short-term memory property of the reservoir unit 30 is low, the signal processor 100 according to the first embodiment can exhibit performance equivalent to that when the short-term memory property is high.

### Second Embodiment

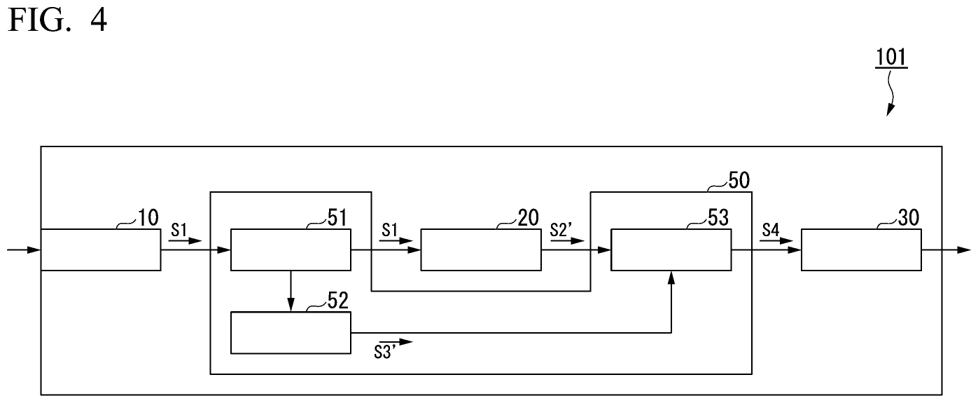

FIG. 4 is a conceptual diagram of a signal processor 101 according to a second embodiment. The signal processor 101 includes an input unit 10, an ADC 20, a reservoir unit 30, and a masking control circuit 50. The masking control circuit 50 is an example of a control circuit in the claims. The signal processor 101 according to the second embodiment is different from the signal processor 100 according to the first embodiment in that the masking control circuit 50 is provided instead of the sampling control circuit 40. In the signal processor 101 according to the second embodiment, the same elements as in the signal processor 100 according to the first embodiment will be referred to by the same reference signs and a description thereof will be omitted.

The masking control circuit 50 detects an analog signal S1 and outputs a control signal S3′ for extracting (masking) a part of a digital signal S2′ to which the analog signal S1 has been converted. The masking control circuit 50 includes, for example, a second detection unit 51, a second control unit 52, and an extraction unit 53. Masking of a signal means that a signal in a period with a mask pattern of “0” is not transmitted and a signal in only a period with a mask pattern of “1” is transmitted by multiplying the mask patterns. When the masking process is performed on a signal, a part of the signal is decimated and the remaining part of the signal is extracted. The control signal S3′ is a signal for instructing not to perform the masking process. At a timing at which the control signal S3′ is not applied, the digital signal S2′ is masked.

The second detection unit 51 is the same as the first detection unit 41. The second detection unit 51 detects an analog signal S1.

The second control unit 52 is the same as the first control unit 42. The second control unit 52 is connected to, for example, the extraction unit 53.

The extraction unit 53 is connected to the ADC 20 and the reservoir unit 30. The extraction unit 53 extracts a digital signal S4 by not masking a part of the digital signal S2′ at a timing at which the control signal S3′ is input and masking a part of the digital signal S2′ at a timing at which the control signal S3′ is not input. The extraction unit 53 inputs the extracted digital signal S4 to the reservoir unit 30. The digital signal S2′ is an example of a first digital signal. The extraction unit 53 is, for example, a program that is stored in a memory of a computer and executed by a processor.

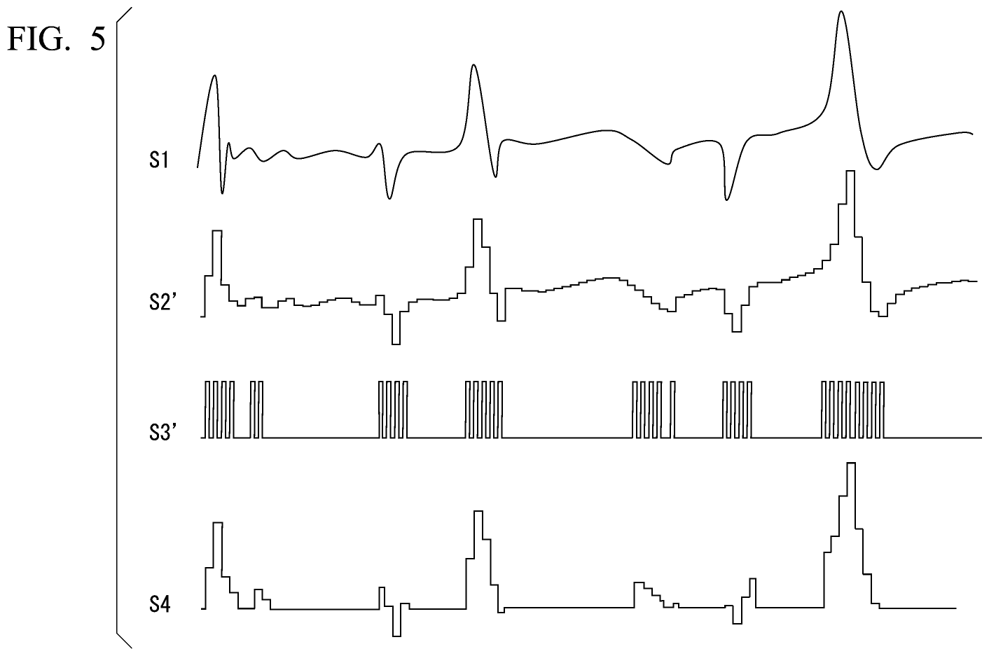

The operation of the signal processor 101 will be described below. FIG. 5 is a diagram illustrating signal processing which is performed by the signal processor 101.

First, an analog signal S1 detected by the sensor or the like is input to the signal processor 100 via the input unit 10. The analog signal S1 propagates to the second detection unit 51 and the ADC 20. The analog signal S1 propagates, for example, from the input unit 10 to the ADC 20, and a part thereof branches and propagates to the second detection unit 51.

The second detection unit 51 determines whether the analog signal S1 satisfies a setting condition. The second control unit 52 outputs a control signal S3′ when the second detection unit 51 determines that the analog signal S1 satisfies the setting condition and does not output the control signal S3′ when the second detection unit 51 determines that the analog signal S1 does not satisfy the setting condition. When the control signal S3′ is a signal for instructing to perform a masking process, the second control unit 52 outputs the control signal S3′ when the second detection unit 51 determines that the analog signal S1 does not satisfy the setting condition and does not output the control signal S3′ when the second detection unit 51 determines that the analog signal S1 satisfies the setting condition.

The setting condition can be set in the same way as in the signal processor 100 according to the first embodiment.

In the signal processor 101, the second control unit 52 sends the control signal S3′ to the extraction unit 53. The extraction unit 53 extracts a digital signal S4 by masking a digital signal S2′ at a timing at which the control signal S3′ is not input and not masking the digital signal S2′ at a timing at which the control signal S3′ is input. A part of the analog signal S1 input to the signal processor 100 is masked by the extraction unit 53, and an unmasked signal is input as the digital signal S4 to the reservoir unit 30.

The number of signals input to the reservoir unit 30 without being masked in a predetermined period in response to the control signal S3′ from the masking control circuit 50 is, for example, equal to or less than short-term memory property of the reservoir unit 30.

The digital signal S4 is input to the reservoir unit 30. All the digital signal S4 may be input to the reservoir unit 30 or a part thereof may be input to the reservoir unit 30. A control method of inputting of a signal to the reservoir unit 30 is the same as in the signal processor 100 according to the first embodiment.

The reservoir unit 30 operates in synchronization with at least a part of the control signal S3′ and performs reservoir computing one time at a timing at which at least a part of the control signal S3′ is input. The reservoir unit 30 may operate in a period in which a signal is not masked in response to the control signal S3′ to nonlinearly convert the input signal Sᵢₙ and to perform inference. It is preferable that the reservoir unit 30 operate in synchronization with at least a part of clocks in a period in which a signal is not masked in response to the control signal S3′ at the time of learning. It is preferable that the output condition of the control signal S3′ at the time of learning be, for example, the same as the output condition of the control signal S3′ at the time of inference.

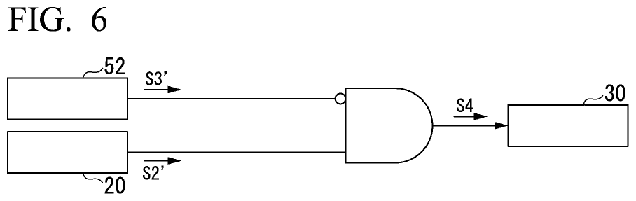

FIG. 6 illustrates an example of a logical circuit for controlling computation of the reservoir unit 30 using the control signal S3′. The logical circuit illustrated in FIG. 6 generates a digital signal S4 which is input to the reservoir unit 30 by masking a part of the digital signal S2′ sampled according to a clock by the ADC 20 in response to the control signal S3′ output from the first control unit 52.

Since the signal processor 101 according to the second embodiment masks a part of the digital signal S2′ to which the analog signal S1 is converted based on the control signal S3′ output based on the analog signal S1, a signal volume input to the reservoir unit 30 is small. Accordingly, the signal processor 101 according to the second embodiment can achieve advantageous effects equivalent to those of the signal processor 100 according to the first embodiment.

### Third Embodiment

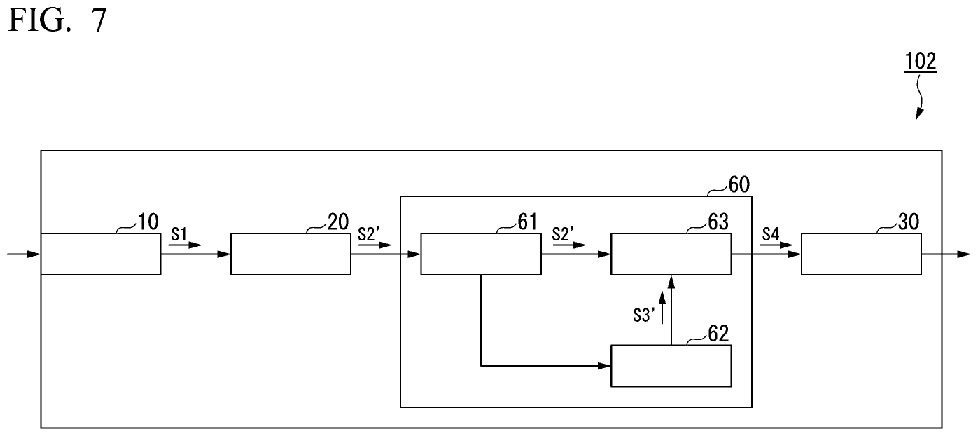

FIG. 7 is a conceptual diagram of a signal processor 102 according to a third embodiment. The signal processor 102 includes an input unit 10, an ADC 20, a reservoir unit 30, and a masking control circuit 60. The masking control circuit 60 is an example of a control circuit in the claims. The signal processor 102 according to the third embodiment is different from the signal processor 100 according to the first embodiment in that the masking control circuit 60 is provided instead of the sampling control circuit 40. In the signal processor 102 according to the third embodiment, the same elements as in the signal processor 100 according to the first embodiment will be referred to by the same reference signs and a description thereof will be omitted.

The masking control circuit 60 detects a digital signal S2′ and outputs a control signal S3′ for extracting a part of the digital signal S2′. The masking control circuit 60 includes, for example, a third detection unit 61, a third control unit 62, and an extraction unit 63.

The third detection unit 61 is connected to, for example, the ADC 20. The third detection unit 61 detects the digital signal S2′. The third detection unit 61 can employ the same configuration as the first detection unit 41 except that a monitoring target is changed from the analog signal S1 to the digital signal S2′.

The third control unit 62 is connected to, for example, the third detection unit 61. The third control unit 62 outputs a control signal S3′ when the digital signal S2′ satisfies a setting condition. The setting condition can be arbitrarily set according to a given task. The third control unit 62 can employ the same configuration as the first control unit 42 except that an analysis target is changed from the analog signal S1 to the digital signal S2′. The third control unit 62 is connected to the extraction unit 63.

The extraction unit 63 is connected to the ADC 20 and the reservoir unit 30. The extraction unit 63 has the same configuration as the extraction unit 53 according to the second embodiment.

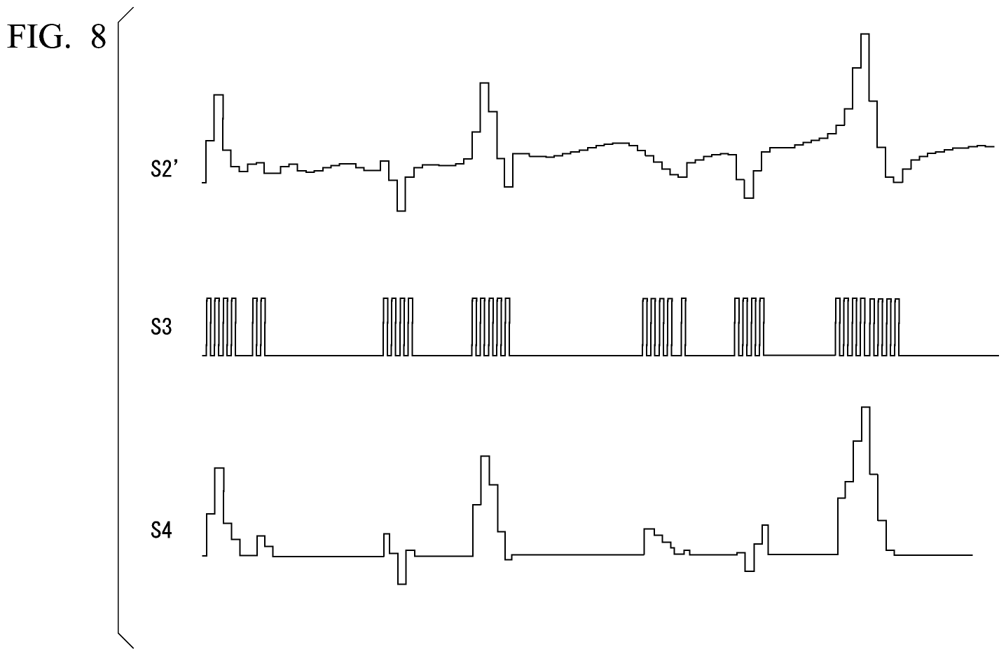

The operation of the signal processor 102 will be described below. FIG. 8 is a diagram illustrating signal processing which is performed by the signal processor 102.

First, an analog signal S1 detected by the sensor or the like is input to the signal processor 102 via the input unit 10. The analog signal S1 propagates to the ADC 20. The analog signal S1 propagates, for example, from the input unit 10 to the ADC 20 and is converted to the digital signal S2′.

The digital signal S2′ propagates to the third detection unit 61 and is monitored by the third detection unit 61. The third detection unit 61 determines whether the digital signal S2′ satisfies a setting condition. The third control unit 62 outputs a control signal S3′ when the third detection unit 61 determines that the digital signal S2′ satisfies the setting condition and does not output the control signal S3′ when the third detection unit 61 determines that the digital signal S2′ does not satisfy the setting condition. The control signal S3′ is a signal for instructing not to perform a masking process. The digital signal S2′ is masked at a timing at which the control signal S3′ is not applied. When the control signal S3′ is a signal for instructing to perform a masking process, the third control unit 62 outputs the control signal S3′ when the third detection unit 61 determines that the digital signal S2′ does not satisfy the setting condition and does not output the control signal S3′ when the third detection unit 61 determines that the digital signal S2′ satisfies the setting condition.

The setting condition can be set in the same way as in the signal processor 100 according to the first embodiment. For example, when a change per unit time of the digital signal S2′ is equal to or greater than a set value, it may be determined that the setting condition is satisfied. For example, the third detection unit 61 may compare the digital signal S2′ with a reference potential and determine that the setting condition is satisfied when a potential based on the digital signal S2′ is higher than the reference potential. For example, the third detection unit 61 may compare an integrated potential based on the digital signal S2′ with the reference potential and determine that the setting condition is satisfied when the integrated potential is higher than the reference potential.

When the control signal S3′ is output based on a judgement criterion of whether the digital signal S2′ satisfies the setting condition, the setting condition may be set using a method other than described above.

For example, a prescribed time-series signal pattern may be determined in advance, and it may be determined that the setting condition is satisfied when a correlation coefficient between the prescribed time-series signal pattern and the digital signal S2′ is equal to or greater than a set value. For example, when an accumulated square error of the prescribed time-series signal pattern and the digital signal S2′ is equal to or greater than a set value, it may be determined that the setting condition is satisfied. A noise pattern may be stored in advance in the masking control circuit 60, and it may be determined that the setting condition is satisfied when a correlation coefficient between the noise pattern and a first digital signal S2′ is equal to or less than a set value. A degree of coincidence between a specific pattern and the digital signal S2′ may be used as a design criterion using a matched filter or the like.

In the signal processor 102, the third control unit 62 sends the control signal S3′ to the extraction unit 63. The extraction unit 63 masks the digital signal S2′ at a timing at which the control signal S3′ is not input and does not mask the digital signal S2′ at a timing at which the control signal S3′ is input. As a result, a digital signal S4 is extracted from the digital signal S2′. A part of the digital signal S2′ input to the signal processor 102 is masked by the extraction unit 63, is converted to the digital signal S4, and is input to the reservoir unit 30.

The number of signals input to the reservoir unit 30 without being masked in a predetermined period in response to the control signal S3′ from the masking control circuit 60 is, for example, equal to or less than short-term memory property of the reservoir unit 30.

The digital signal S4 is input to the reservoir unit 30. All the digital signal S4 may be input to the reservoir unit 30 or a part thereof may be input to the reservoir unit 30. A control method of inputting of a signal to the reservoir unit 30 is the same as in the signal processor 100 according to the first embodiment.

The reservoir unit 30 operates in synchronization with at least a part of the control signal S3′ and performs reservoir computing one time at a timing at which at least a part of the control signal S3′ is input. It is preferable that the reservoir unit 30 operate in synchronization with a clock of the period in which a signal is not masked in response to the control signal S3′. It is preferable that the output condition of the control signal S3′ at the time of learning be, for example, the same as the output condition of the control signal S3′ at the time of inference.

Since the signal processor 102 according to the third embodiment masks a part of the digital signal S2′ based on the control signal S3′ and converts the part to the digital signal S4, a signal volume input to the reservoir unit 30 is small. Accordingly, the signal processor 102 according to the third embodiment can achieve advantageous effects equivalent to those of the signal processor 100 according to the first embodiment.

### Fourth Embodiment

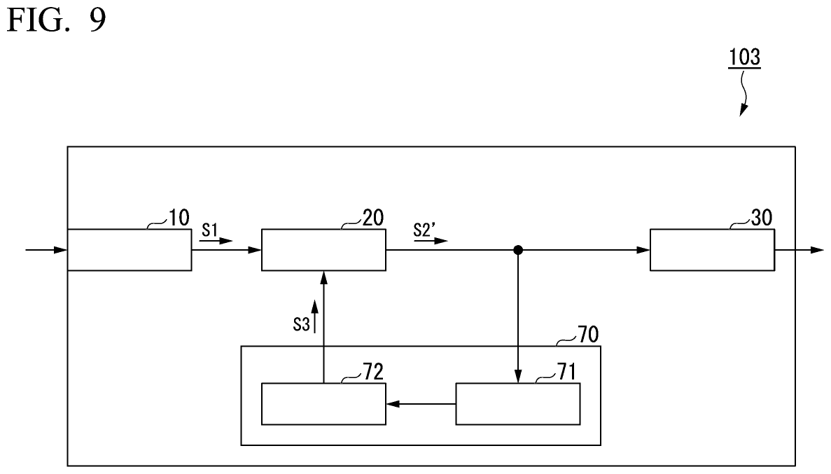

FIG. 9 is a conceptual diagram of a signal processor 103 according to a fourth embodiment. The signal processor 103 includes an input unit 10, an ADC 20, a reservoir unit 30, and a sampling control circuit 70. The sampling control circuit 70 is an example of a control circuit in the claims. The signal processor 103 according to the fourth embodiment is different from the signal processor 100 according to the first embodiment in that the sampling control circuit 70 is provided instead of the sampling control circuit 40. In the signal processor 103 according to the fourth embodiment, the same elements as in the signal processor 100 according to the first embodiment will be referred to by the same reference signs and a description thereof will be omitted.

The sampling control circuit 70 detects a digital signal S2′ and outputs a control signal S3 for extracting a part of the digital signal S2′. The sampling control circuit 70 includes, for example, a fourth detection unit 71 and a fourth control unit 72.

The fourth detection unit 71 is connected to, for example, the ADC 20. The fourth detection unit 71 detects the digital signal S2′. The fourth detection unit 61 can employ the same configuration as the first detection unit 41 except that a monitoring target is changed from the analog signal S1 to the digital signal S2′.

The fourth control unit 72 is connected to, for example, the fourth detection unit 71. The fourth control unit 72 outputs a control signal S3 when the digital signal S2′ satisfies a setting condition. The setting condition can be arbitrarily set according to a given task. The fourth control unit 72 can employ the same configuration as the first control unit 42 except that an analysis target is changed from the analog signal S1 to the digital signal S2′.

The operation of the signal processor 103 will be described below. First, an analog signal S1 detected by the sensor or the like is input to the signal processor 103 via the input unit 10. The analog signal S1 propagates to the ADC 20. The analog signal S1 is converted to the digital signal S2′ by the ADC 20.

The digital signal S2′ propagates to the fourth detection unit 71 and is monitored by the fourth detection unit 71. The fourth detection unit 71 determines whether the digital signal S2′ satisfies a setting condition. The fourth control unit 72 outputs a control signal S3 when the fourth detection unit 71 determines that the digital signal S2′ satisfies the setting condition and does not output the control signal S3 when the fourth detection unit 71 determines that the digital signal S2′ does not satisfy the setting condition. The setting condition can be set in the same way as in the signal processor 102 according to the third embodiment.

The fourth control unit 72 outputs the control signal S3 and sends the control signal to the ADC 20. The control signal S3 is a signal for instructing to change a sampling timing of the ADC 20. The sampling timing of the ADC 20 changes, for example, according to the control signal S3. When the sampling tuning is changed by the control signal S3, a period (a sampling rate) in which the analog signal S1 is converted to the digital signal S2′ changes. The digital signal S2′ changes in response to application of the control signal S3. The digital signal S2′ is an example of a first digital signal.

The number of signals input to the reservoir unit 30 in a predetermined period in response to the control signal S3 from the sampling control circuit 40 is, for example, equal to or less than short-term memory property of the reservoir unit 30.

The digital signal S2′ is input to the reservoir unit 30. The reservoir unit 30 operates in synchronization with at least a part of the control signal S3. The reservoir unit 30 may operate synchronously every time the control signal S3 is output. Synchronous operation means that the reservoir unit 30 performs reservoir computing one time at a timing at which the control signal S3 is output.

It is also preferable that the reservoir unit 30 operate in synchronization with at least a part of the control signal S3′ at the time of learning. It is preferable that the output condition of the control signal S3 at the time of learning be, for example, the same as the output condition of the control signal S3 at the time of inference.

As described above, since the signal processor 103 according to the fourth embodiment samples the analog signal S1 input to the signal processor 103 and converts a part of the sampled signal to the digital signal S2′, a signal volume input to the reservoir unit 30 is small. Accordingly, the signal processor 103 according to the fourth embodiment can achieve advantageous effects equivalent to those of the signal processor 100 according to the first embodiment.

### Fifth Embodiment

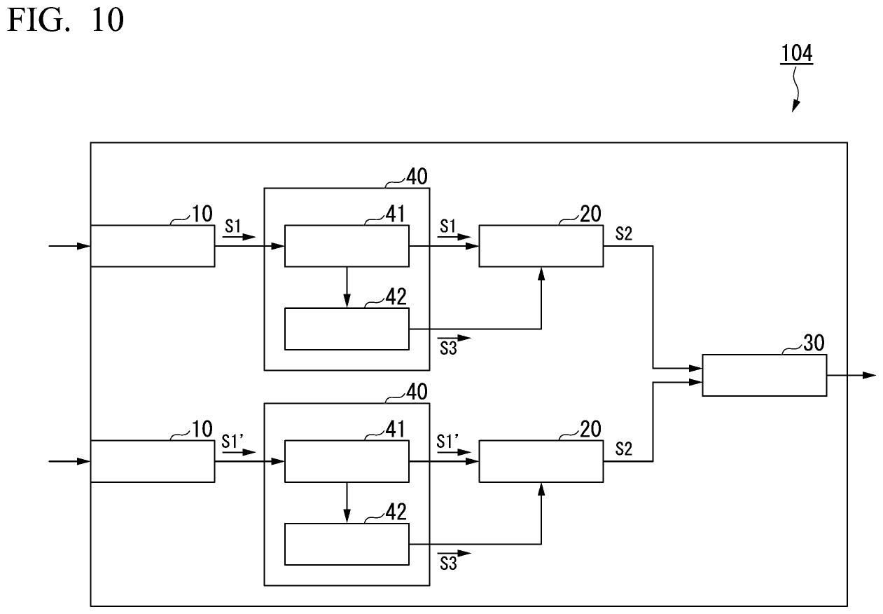

FIG. 10 is a conceptual diagram of a signal processor 104 according to a fifth embodiment. The signal processor 104 is different from the signal processor 100 according to the first embodiment in that a plurality of analog signals S1 and S1′ are input to the signal processor 104. The analog signal S1′ is an example of a second analog signal. In the signal processor 104 according to the fifth embodiment, the same elements as in the signal processor 100 according to the first embodiment will be referred to by the same reference signs and a description thereof will be omitted.

The signal processor 104 includes two input units 10, two ADCs 20, two sampling control circuits 40, and a reservoir unit 30. The signal processor 104 separately includes the input unit 10, the ADC 20, and the sampling control circuit 40 for processing the analog signal S1 and the input unit 10, the ADC 20, and the sampling control circuit 40 for processing the analog signal S1′. One thereof may be shared. Two analog signals S1 and S1′ are input to the signal processor 104, but the number of analog signals may be equal to or greater than 3.

The signal processor 104 according to the fifth embodiment can achieve advantageous effects equivalent to those of the signal processor 100 according to the first embodiment. When the number of analog signals input to the signal processor 104 is two or more, more information is input to the reservoir unit 30 and thus the reservoir unit can perform more advanced processing.

While embodiments of the present invention have been described above in detail with reference to the drawings, the configurations of the embodiments, combinations thereof, and the like are merely examples and can be subjected to additions, omissions, replacements, and other modifications of elements without departing from the gist of the present invention.

For example, the configuration illustrated in FIG. 10 may be applied to FIGS. 4, 7, and 9. That is, the number of input analog signals in the signal processor 101 according to the second embodiment, the signal processor 102 according to the third embodiment, and the signal processor 103 according to the fourth embodiment may be two or more.

### REFERENCE SIGNS LIST

10 Input unit
20 Analog-digital converter (ADC)
30 Reservoir unit
40, 70 Sampling control circuit
50, 60 Masking control circuit
41 First detection unit
42 First control unit
51 Second detection unit
52 Second control unit
61 Third detection unit
62 Third control unit
71 Fourth detection unit
72 Fourth control unit
53, 63 Extraction unit
100, 101, 102, 103, 104 Signal processor
S1, S1′ Analog signal
S2, S2′, S4 Digital signal
S3 Sampling control signal

1. A signal processor comprising:
an input unit configured to receive a first analog signal;
an analog-digital converter configured to convert the first analog signal to a first digital signal;
a control circuit configured to detect the first analog signal or the first digital signal and to output a control signal for extracting a part of the first analog signal or the first digital signal; and
a reservoir unit configured to receive at least a part of the first digital signal and to operate in synchronization with at least a part of the control signal.

2. The signal processor according to claim 1, wherein the control circuit includes:
a first detection unit configured to detect the first analog signal; and
a first control unit configured to output the control signal when the first analog signal satisfies a setting condition,
wherein the first control unit sends the control signal to the analog-digital converter, and
wherein the analog-digital converter changes a sampling timing at which the first analog signal is converted to the first digital signal at a timing at which the control signal has been input.

3. The signal processor according to claim 1, wherein the control circuit includes:
a second detection unit configured to detect the first analog signal;
a second control unit configured to output the control signal when the first analog signal satisfies a setting condition; and
an extraction unit configured to extract a part of the first digital signal at a timing at which the control signal has been input and to input the extracted part of the first digital signal to the reservoir unit.

4. The signal processor according to claim 1, wherein the control circuit includes:
a third detection unit configured to detect the first digital signal;
a third control unit configured to output the control signal when the first digital signal satisfies a setting condition; and
an extraction unit configured to extract a part of the first digital signal at a timing at which the control signal has been input and to input the extracted part of the first digital signal to the reservoir unit.

5. The signal processor according to claim 1, wherein the control circuit includes:
a fourth detection unit configured to detect the first digital signal; and
a fourth control unit configured to output the control signal when the first digital signal satisfies a setting condition,
wherein the fourth control unit sends the control signal to the analog-digital converter, and
wherein the analog-digital converter changes a sampling timing at which the first analog signal is converted to the first digital signal at a timing at which the control signal has been input.

6. The signal processor according to claim 1, wherein the number of signals input to the reservoir unit in a predetermined period in accordance with the control signal from the control circuit is equal to or less than short-term memory property of the reservoir unit.

7. The signal processor according to claim 1, wherein the input unit additionally receives a second analog signal.

8. The signal processor according to claim 1, wherein the reservoir unit performs reservoir computing one time in synchronization with every output of the control signal.

9. The signal processor according to claim 1, wherein the control circuit outputs the control signal when a correlation coefficient between a prescribed time-series signal pattern and the first analog signal or the first digital signal is equal to or greater than a set value.

10. The signal processor according to claim 1, wherein the control circuit outputs the control signal when an accumulated square error of a prescribed time-series signal pattern and the first analog signal or the first digital signal is equal to or greater than a set value.

11. The signal processor according to claim 1, wherein the control circuit stores a noise pattern and outputs the control signal when a correlation coefficient between the noise pattern and the first analog signal or the first digital signal is equal to or less than a set value.

12. The signal processor according to claim 1, wherein the control circuit outputs the control signal when a change per unit time of the first analog signal or the first digital signal is equal to or greater than a set value.

13. The signal processor according to claim 1, wherein the reservoir unit operates in synchronization with at least a part of the control signal and performs learning based on an input signal, and
wherein an output condition of the control signal at the time of learning is the same as an output condition of the control signal at the time of inference.

14. The signal processor according to claim 1, wherein the reservoir unit is realized as a state machine by logical circuits, and
wherein an operation signal of the state machine is synchronized with at least a part of the control signal and the reservoir unit performs reservoir computing one time based on the operation signal.

15. The signal processor according to claim 1, wherein the reservoir unit is realized as a physical reservoir including elements or circuits, and
wherein an input signal is input to the physical reservoir in synchronization with at least a part of the control signal and the reservoir unit performs reservoir computing one time based on the input signal.

16. A signal processing method comprising:
detecting a first analog signal or a first digital signal to which the first analog signal is converted;
outputting a control signal for extracting a part of the first analog signal or the first digital signal when the first analog signal or the first digital signal satisfies a setting condition; and
performing inference through reservoir computing with a signal extracted using the control signal as an input.
